(19) United States
(12) Patent Application Publication
(10) Pub. No.: US 2025/0170621 A1
(43) Pub. Date: May 29, 2025

(54) SUBSTRATE PROCESSING APPARATUS AND SUBSTRATE PROCESSING METHOD

(71) Applicant: SEMES CO., LTD., Cheonan-si (KR)

(72) Inventors: Sune Gi WANG, Hwaseong-si (KR); Young Hun JUNG, Asan-si (KR); Chang Woo SON, Anseong-si (KR); Jae Wook SHIN, Cheonan-si (KR); Min Goo KANG, Asan-si (KR)

(73) Assignee: SEMES CO., LTD., Cheonan-si (KR)

(21) Appl. No.: 18/947,084

(22) Filed: Nov. 14, 2024

(30) Foreign Application Priority Data
Nov. 24, 2023 (KR) 10-2023-0165714

(51) Int. Cl. B08B 3/14; B01D 36/00; B08B 3/08; B08B 13/00; H01L 21/02

(52) U.S. Cl. CPC B08B 3/14; B01D 36/001; B08B 3/08; B08B 13/00; H01L 21/02057

(57) ABSTRACT

The apparatus including a liquid discharge unit for discharging a treatment solution in a liquid form onto the substrate supported on a support unit in a processing space; and a liquid supply unit including a tank storing the treatment solution, a supply line connecting the tank and the liquid discharge unit, and a filter installed between the tank and the supply line, in which the filter includes a vent port for discharging a liquid containing bubbles to the outside of the filter, and the liquid supply unit further includes a circulation line which is connected to the vent port of the filter and circulates the treatment solution discharged from the vent port of the filter to a line connected to an inlet port of the filter.

### CROSS-REFERENCE TO RELATED APPLICATIONS

This application claims priority to and the benefit of Korean Patent Application No. 10-2023-0165714 filed in the Korean Intellectual Property Office on Nov. 24, 2023, the entire contents of which are incorporated herein by reference.

### TECHNICAL FIELD

The present invention relates to a substrate processing apparatus and a substrate processing method that process a substrate.

### BACKGROUND ART

To manufacture semiconductor devices, various processes, such as photography, deposition, ashing, etching, and ion implantation, are performed. In addition, before and after these processes are performed, a cleaning process of cleaning particles remaining on the substrate is performed.

The cleaning process further includes a process for supplying a treatment solution to a substrate that is supported on a spin head and rotates, a process of removing the treatment solution from the substrate by supplying a cleaning solution, such as deionized water (DIW), to the substrate, a process of supplying an organic solvent, such as an isopropyl alcohol (IPA) liquid, having lower surface tension than the cleaning solution, to the substrate to substitute the cleaning solution on the substrate with the organic solvent, and a drying process of removing the substituted organic solvent from the substrate.

In this case, the treatment solution is supplied in a mixed state from the tank, and the line supplying the treatment solution is equipped with a filter to filter the treatment solution.

In this case, the filter that filters the treatment solution is formed with a vent port to discharge the treatment solution, and is connected to circulate the treatment solution inside the filter to the tank side.

However, there is a problem that the treatment solution discharged from the vent port of the filter to the tank contains particles and contaminates the treatment solution.

As a result, the treatment solution discharged from the vent port of the filter is sometimes discarded, which increases the cost of substrate manufacturing.

In addition, the treatment solution discharged from the vent port may generate bubbles during the filter replacement process, and these bubbles may cause process defect when the bubbles flow into the substrate treatment process.

### SUMMARY OF THE INVENTION

The present invention has been made in an effort to provide a substrate processing apparatus and a substrate processing method that ensure that a contaminated treatment solution discharged from a vent port of a filter does not cause process defect.

The present invention has been made in an effort to provide a substrate processing apparatus and a substrate processing method that reuse a contaminated treatment solution discharged from a vent port of a filter, thereby reducing manufacturing costs.

The present invention has been made in an effort to provide a substrate processing apparatus and a substrate processing method that prevent a treatment solution discharged from a vent port of a filter from entering a process when the treatment solution contains bubbles.

The problem to be solved by the present invention is not limited to the above-mentioned problems, and the problems not mentioned will be clearly understood by those skilled in the art from the descriptions below.

The problem to be solved by the present invention is not limited to the above-mentioned problems, and the problems not mentioned will be clearly understood by those skilled in the art from the descriptions below.

An exemplary embodiment of the present invention provides an apparatus for processing a substrate, the apparatus including: a chamber having a processing space; a support unit for supporting a substrate in the processing space; a liquid discharge unit for discharging a treatment solution in a liquid form onto the substrate supported on the support unit; and a liquid supply unit including a tank storing the treatment solution, a supply line connecting the tank and the liquid discharge unit, and a filter installed between the tank and the supply line, in which the filter includes: an inlet port through which the treatment solution flows into the filter from the tank; an outlet port through which the treatment solution flows out from the filter to the liquid discharge unit; and a vent port for discharging a liquid containing bubbles to the outside of the filter, and the liquid supply unit further includes a circulation line which is connected to the vent port of the filter and circulates the treatment solution discharged from the vent port of the filter to a line connected to the inlet port of the filter.

According to the exemplary embodiment, the liquid supply unit may include: a drain line branched from the circulation line and draining the treatment solution discharged from the vent port; and a valve unit for controlling a flow path of the treatment solution so that the treatment solution discharged from the vent port selectively flows to the drain line or the line connected to the inlet port.

According to the exemplary embodiment, the liquid supply unit may further include a valve controller that controls the valve unit, and the valve controller may control the valve unit so that the treatment solution discharged from the vent port flows to the line connected to the inlet port when the substrate is processed.

According to the exemplary embodiment, the liquid supply unit may further include a valve controller that controls the valve unit, and the valve controller may control the valve unit so that the treatment solution discharged from the vent port flows to the drain line during an initial setup of the filter. In this case, the initial setup may include replacement of the filter.

According to the exemplary embodiment, the liquid supply unit may further include: a bubble detection sensor for detecting bubbles in the circulation line; and a valve controller for controlling the valve unit, and the valve controller may cause the treatment solution discharged from the vent port to flow to the drain line when the bubbles detected by the bubble detection sensor are equal to or greater than a set amount.

According to the exemplary embodiment, the valve controller may control the valve unit so that the treatment solution discharged from the vent port flows to the line connected to the inlet port when the bubbles detected by the bubble detection sensor are less than the set amount.

According to the exemplary embodiment, the liquid supply unit may further include a valve controller that controls the valve unit, and the valve controller may control the valve unit so that the treatment solution discharged from the vent port flows to the drain line during an initial setup for supplying the treatment solution to the substrate, and then so that the treatment solution discharged from the vent port flows to the line connected to the inlet port.

According to the exemplary embodiment, the valve unit may be a three-way valve installed at a point where the circulation line and the drain line are connected.

According to the exemplary embodiment, the bubble detection sensor may be disposed between the vent port and the three-way valve.

According to the exemplary embodiment, the liquid supply unit may further include: a measurement line having one end connected to the outlet port of the filter; and a densitometer installed on the measurement line, and the measurement line may have the other end connected to the circulation line.

According to the exemplary embodiment, the filter may be a membrane filter.

According to the exemplary embodiment, the liquid supply unit may further include a drain valve installed in the drain line and opening and closing a passage of the drain line, and the drain port may be located at a bottom end of the filter, and when the drain valve is open, the treatment solution may be drained by falling, and the vent port may be located at a top end of the filter, and when the treatment solution is fully filled in the filter, the treatment solution may be discharged upward.

Another exemplary embodiment of the present invention provides a method of processing a substrate, the method including: processing a substrate by supplying a treatment solution from a tank to a substrate via a filter, in which the treatment solution flows into the filter through an inlet port of the filter, and the treatment solution filtered from the filter is discharged from the filter through an outlet port of the filter, bubbles or the treatment solution containing bubbles in the filter is discharged from the filter through a vent port of the filter while the treatment solution flows from the inlet port to the outlet port, and the treatment solution discharged from the vent port of the filter flows through a path selected from a first path through which the treatment solution is circulated upstream of the filter and then flowed into the inlet port of the filter again, and a second path through which the treatment solution is discharged from the vent port of the filter and then drained to the outside.

According to the exemplary embodiment, during the processing of the substrate, the treatment solution discharged from the vent port of the filter may flow to the second path at a beginning of a supply at which the treatment solution flows through the filter, and thereafter, the treatment solution discharged from the vent port of the filter may flow to the first path.

According to the exemplary embodiment, the method may further include detecting bubbles in the treatment solution discharged from the vent port, in which when the amount of bubbles detected is equal to or greater than a set value, the treatment solution discharged from the vent port of the filter may flow to the second path, and when the amount of bubbles detected is less than the set value, the treatment solution discharged from the vent port of the filter may flow to the first path.

According to the exemplary embodiment, in a setup operation of the apparatus before supplying the treatment solution to the substrate, the treatment solution discharged from the vent port of the filter may flow to the second path.

According to the exemplary embodiment, in a state where the treatment solution is circulated by connecting the outlet port of the filter and the inlet port of the filter by a line, a densitometer may be installed in the line to measure the concentration of the treatment solution.

According to the exemplary embodiment, a drain port may be located at a bottom end of the filter, the vent port is located at a top end of the filter, and the treatment solution may fall to a bottom end of the drain port and be discharged to the second path, and when the treatment solution is fully filled in the filter, the treatment solution may be discharged to the first path from a top end of the vent port.

Still another exemplary embodiment of the present invention provides an apparatus for processing a substrate, the apparatus including: a chamber having a processing space; a support unit for supporting a substrate in the processing space; a liquid discharge unit for discharging a treatment solution in a liquid form onto a substrate supported on the support unit; and a liquid supply unit including a tank storing the treatment solution, a supply line connecting the tank and the liquid discharge unit, and a filter installed between the tank and the supply line, in which the filter includes: an inlet port through which the treatment solution flows into the filter from the tank; an outlet port through which the treatment solution flows out from the filter to the liquid discharge unit; and a vent port for discharging a liquid containing bubbles to the outside of the filter, and the liquid supply unit further includes: a circulation line which is connected to the vent port of the filter and circulates the treatment solution discharged from the vent port of the filter to a line connected to the inlet port of the filter; a drain line branched from the circulation line and draining the treatment solution discharged from the vent port; a measurement line having one end connected to the outlet port of the filter and the other end connected to the circulation line; a densitometer installed on the measurement line; a valve unit for controlling a flow path of the treatment solution so that the treatment solution discharged from the vent port selectively flows to the drain line or the line connected to the inlet port; a bubble detection sensor for detecting bubbles in the circulation line; and a valve controller for controlling the valve unit, and the valve controller controls the valve unit to cause the treatment solution discharged from the vent port to flow to the drain line when the bubbles detected by the bubble detection sensor are equal to or greater than a set amount, and to cause the treatment solution discharged from the vent port to flow to the line connected to the inlet port when the bubbles detected by the bubble detection sensor are less than the set amount, and the valve controller controls the valve unit so that the treatment solution discharged from the vent port flows to the drain line at a beginning at which the treatment solution is supplied to the substrate, and thereafter, the treatment solution discharged from the vent port flows to the line connected to the inlet port.

The present invention has the effect of reducing process defects due to the treatment solution by re-filtering the contaminated treatment solution discharged from the vent port and reducing the treatment solution by reusing the treatment solution, since the treatment solution discharged from the vent port of the filter is circulated to the inlet port of the filter.

In addition, the present invention has the effect of preventing process defects due to the bubbles by discharging the treatment solution containing bubbles when the treatment solution from the vent port of the filter contains bubbles.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a top plan view illustrating a substrate processing facility according to an exemplary embodiment of the present invention.

FIG. 2 is a cross-sectional view illustrating a substrate processing apparatus of FIG. 1.

FIG. 3 is a view schematically illustrating a liquid supply unit of FIG. 2.

FIG. 4 is a diagram schematically illustrating a circulation unit connected with a filter illustrated in FIG. 3.

FIGS. 5 and 6 are diagrams illustrating a movement process of a treatment solution flowing in a liquid supply unit of FIG. 3.

FIG. 7 is a flowchart illustrating a process of processing a substrate by using the apparatus of FIG. 3.

FIG. 8 is a cross-sectional view of a modified example of the substrate processing apparatus illustrated in FIG. 2.

FIG. 9 is a diagram illustrating a path through which the circulation unit illustrated in FIG. 4 filters the treatment solution.

FIG. 10 is a diagram illustrating a path through which the circulation unit illustrated in FIG. 9 discharges the treatment solution including generated bubbles.

FIG. 11 is a diagram illustrating the flow of the discharge of the treatment solution from the filter of FIGS. 9 and 10 with arrows.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the apparatus in the figures is turned over, elements described as “below” or “beneath” other elements or features would then be oriented “above” the other elements or features. Thus, the example term “below” can encompass both an orientation of above and below. The apparatus may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to apparatus used for other types of substrate processing, in addition to wafers.

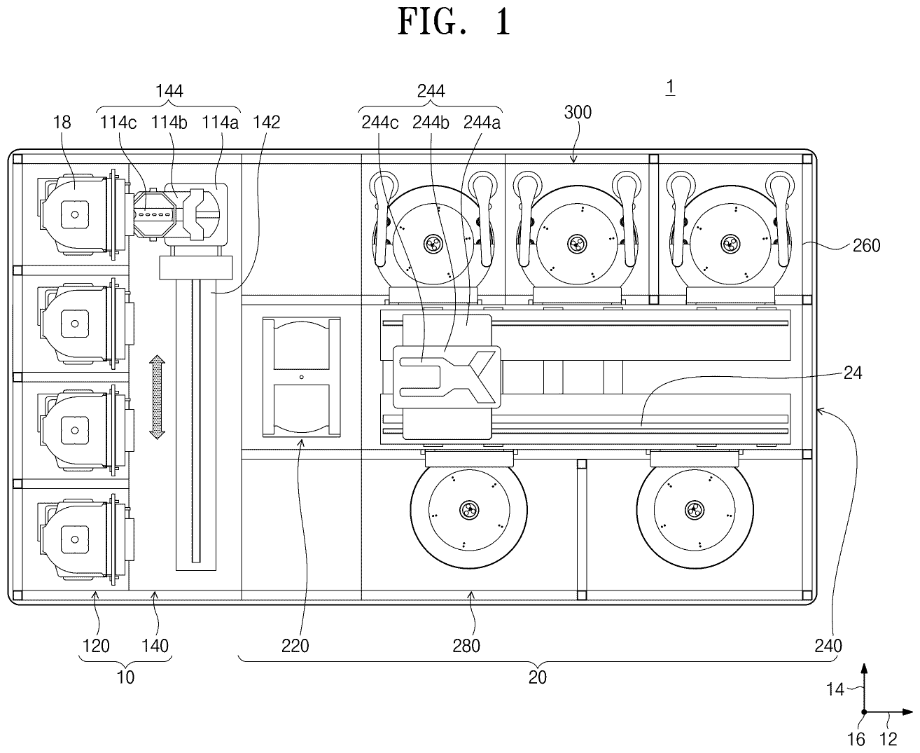

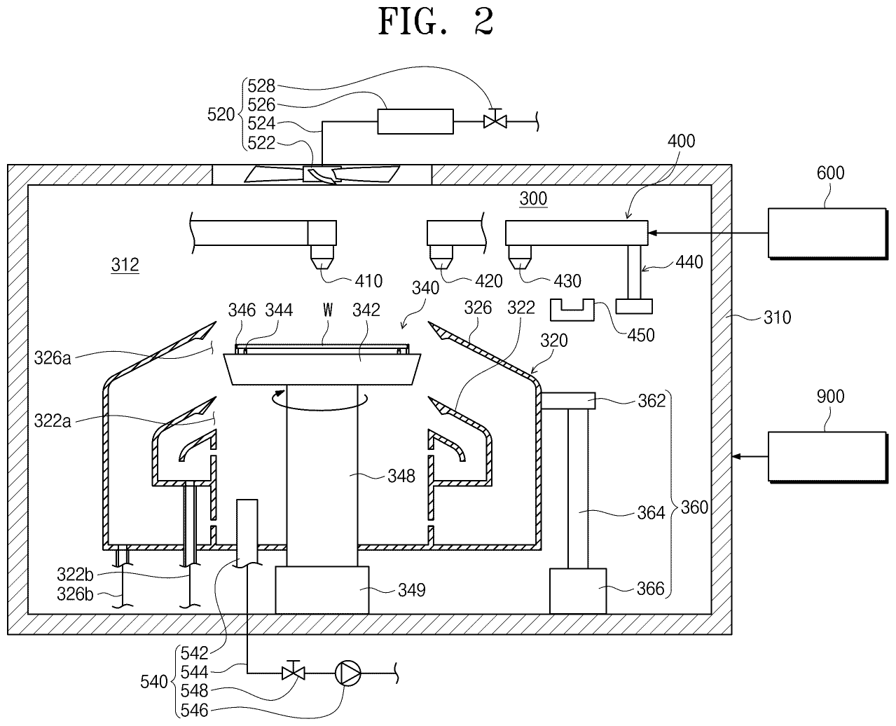

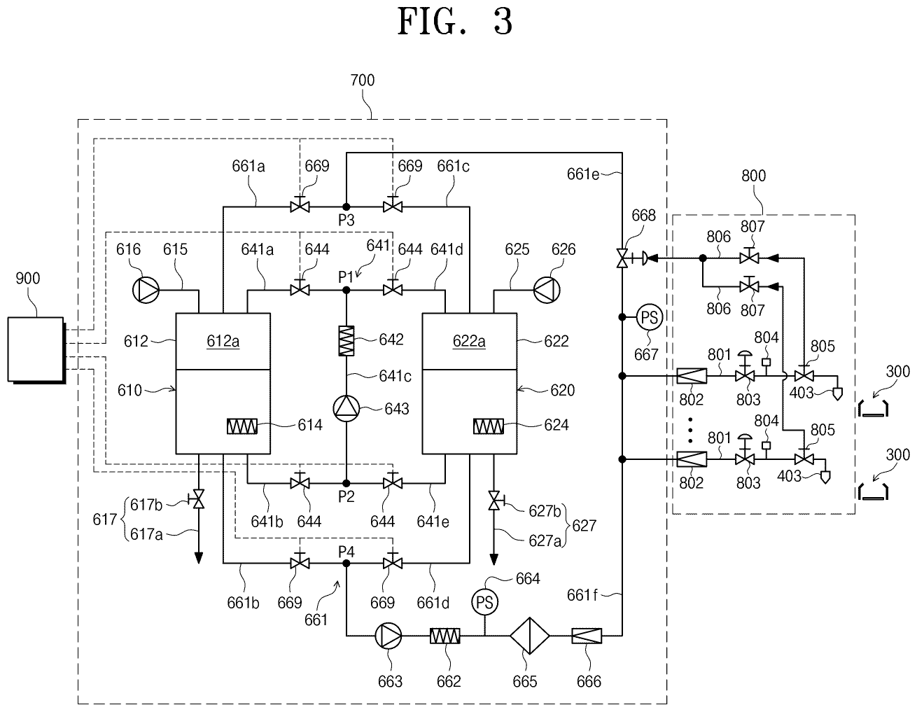

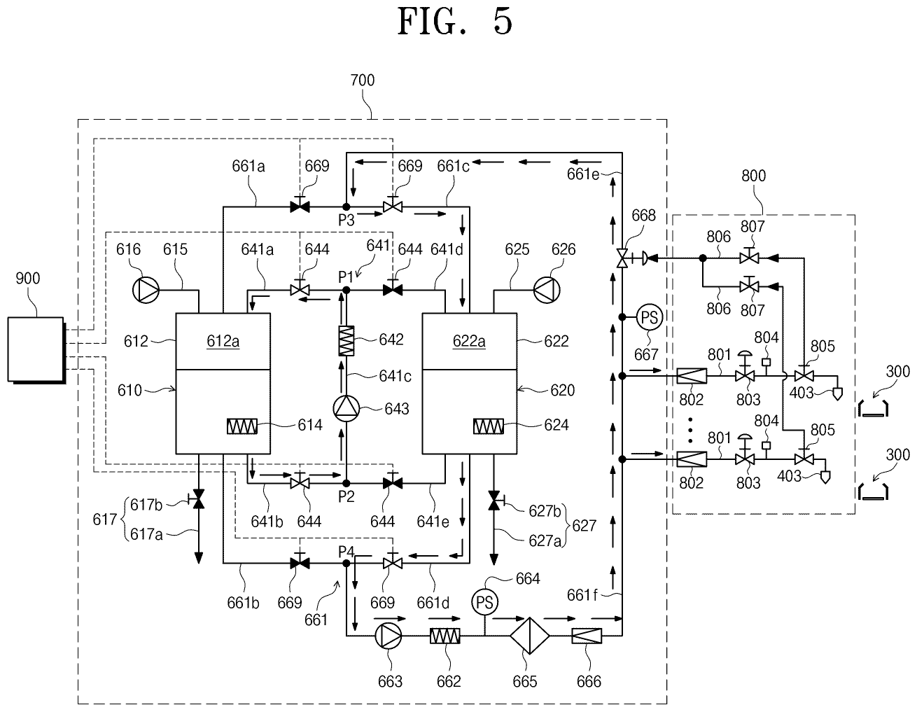

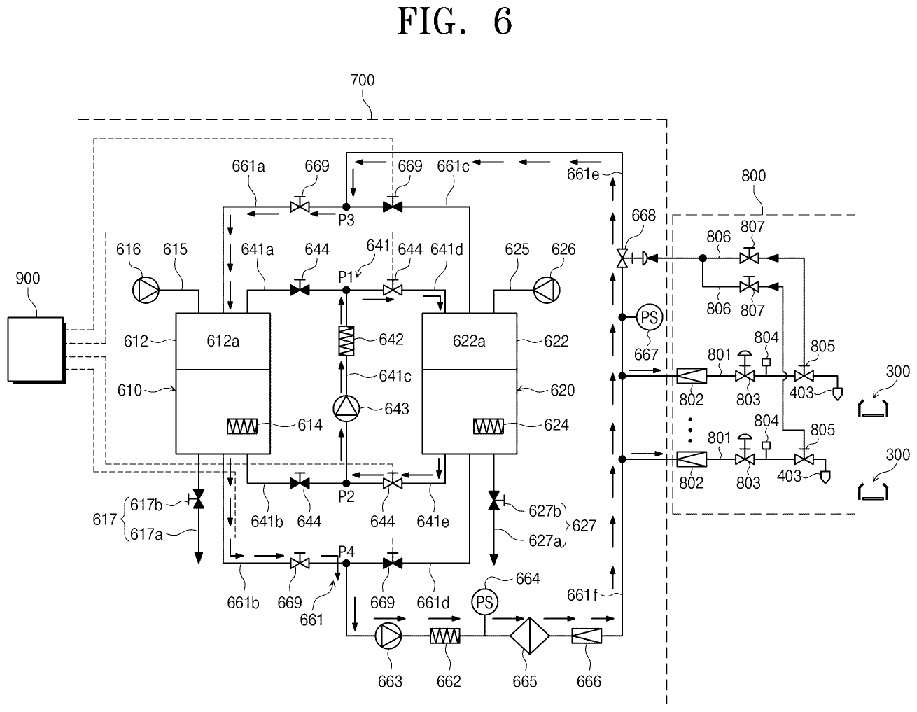

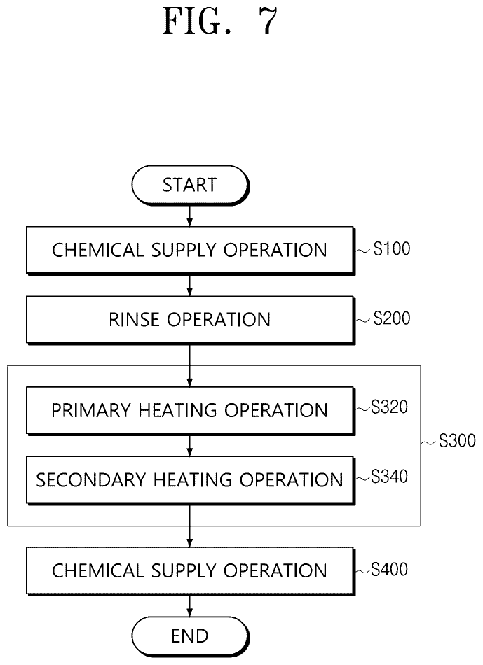

FIG. 1 is a top plan view illustrating a substrate processing facility according to an exemplary embodiment of the present invention. FIG. 2 is a cross-sectional view illustrating a substrate processing apparatus of FIG. 1. FIG. 3 is a view schematically illustrating a liquid supply unit of FIG. 2. FIGS. 5 and 6 are diagrams illustrating a movement process of a treatment solution flowing in a liquid supply unit of FIG. 3. FIG. 7 is a flowchart illustrating a process of processing a substrate by using the apparatus of FIG. 3.

Referring to FIGS. 1 to 7, a substrate processing facility 1 includes an index module 10 and a process processing module 20, and the index module 10 has a load port 120 and a transfer frame 140. The load port 120, the transfer frame 140, and the process processing module 20 are arranged in sequential rows. Hereinafter, a direction in which the load port 120, the transfer frame 140, and the process processing module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 18 in which a substrate W is accommodated is seated on the load port 120. A plurality of load ports 120 is provided and is arranged in a line along the second direction 14. In FIG. 1, it is illustrated that four load ports 120 are provided. However, the number of load ports 120 may be increased or decreased depending on conditions, such as process efficiency and footprint of the process processing module 20. Slots (not illustrated) provided to support an edge of the substrate are formed in the carrier 18. A plurality of slots is provided in the third direction 16, and the substrates are positioned within the carrier so as to be stacked while being spaced apart from each other in the third direction 16. As the carrier 18, a Front Opening Unified Pod (FOUP) may be used.

The process processing module 20 may include a buffer unit 20, a transfer chamber 240, and process chambers 260 and 280. The transfer chamber 240 is disposed so that a longitudinal direction thereof is parallel to the first direction 12. The process chambers 260 and 280 are disposed on opposite sides of the transfer chamber 240 in the second direction 14. The process chambers 260 may be provided to be symmetrical to each other relative to the transfer chamber 240. Some of the process chambers 260 and 280 are disposed along the longitudinal direction of the transfer chamber 240. Additionally, some of the process chambers 260 and 280 are arranged to be stacked on top of each other. That is, the process chambers 260 and 280 may be disposed in an array of A×B (A and B are natural numbers equal to or greater than 1) on opposite sides of the transfer chamber 240. Here, A is the number of process chambers 260 and 280 provided in a line along the first direction 12, and B is the number of process chambers 260 and 280 provided in a line along the third direction 16. When four or six process chambers 260 and 280 are provided on each of the opposite sides of the transfer chamber 240, the process chambers 260 and 280 may be disposed in an array of 2×2 or 3×2. The number of process chambers 260 and 280 may be increased or decreased. Unlike the foregoing, the process chamber 260 may be provided only to one side of the transfer chamber 240. In addition, the process chambers 260 and 280 may be provided as a single layer on one side and the opposite sides of the transfer chamber 240. In addition, the process chambers 260 and 280 may be provided in various arrangements unlike the above.

The process chambers 260 and 280 of the present exemplary embodiment may be categorized as including a cleaning chamber and a drying chamber. In this case, the cleaning chamber may be a substrate processing facility for cleaning the substrate, which will be described below, and the drying chamber may be a substrate processing facility for drying the substrate.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. The buffer unit 220 is provided with slots (not illustrated) on which the substrate W is placed therein, and the slots (not illustrated) are provided in plurality so as to be spaced apart from each other in the third direction 16. In the buffer unit 220, a side facing the transfer frame 140 and a side facing the transfer chamber 240 are each open.

The transfer frame 140 transfers the substrate W between the carrier 18 seated at the load port 120 and the buffer unit 220. The transfer frame 140 is provided with an index rail 142 and an index robot 144. The index rail 142 is provided so that a longitudinal direction thereof is parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 18, and another some of the plurality of index arms 144c may be used when the substrate W is transferred from the carrier 130 to the process processing module 20. This may prevent the particles generated from the substrate W before the process processing from being attached to the substrate W after the process processing in the process in which the index robot 144 loads and unloads the substrate W.

The transfer chamber 240 transfers the substrate W between the buffer unit 220 and the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b.

Hereinafter, a substrate processing apparatus 300 provided in the process chamber 260 will be described. In the present exemplary embodiment, the case where the substrate processing facility 1 performs a liquid treatment process on the substrate will be described as an example. The liquid treating process further includes a process of cleaning a substrate.

FIG. 2 is a cross-sectional view illustrating a substrate processing apparatus of FIG. 1. Referring to FIG. 2, a substrate processing apparatus 300 further includes a chamber 310, a processing container 320, a spin head 340, a lifting unit 360, a liquid discharge unit 400, an airflow formation unit 500, a liquid supply unit 600, and a controller 900. The chamber 310 provides a processing space 312 in which a process for processing the substrate W is performed.

The processing container 320 is positioned in the processing space 312 and is provided in the shape of a cup with an open top. When viewed from above, the processing container 320 is positioned to overlap an exhaust pipe. The processing container 320 includes an internal recovery container 322 and an external recovery container 326. Each of the recovery containers 322 and 326 recovers a different treatment solution from the treatment solutions used in the process. The internal recovery container 322 is provided in the shape of an annular ring surrounding the spin head 340, and the external recovery container 326 is provided in the shape of an annular ring surrounding the internal recovery container 322. An inner space 322a of the internal recovery container 322 and a space 326a between the external recovery container 326 and the inner recovery container 322 function as inlet ports for the treatment solution to flow into the internal recovery container 322 and the external recovery container 326, respectively. Circulation lines 322b and 326b are connected to the bottom surfaces of the recovery containers 322 and 326, respectively, to extend vertically in the down direction. Each of the circulation lines 322b and 326b functions as a discharge pipe to discharge the treatment solution that has flowed through the respective recovery containers 322 and 326. The discharged treatment solution may be reused through an external treatment solution regeneration system (not illustrated).

The spin head 340 is provided as a substrate support unit 340 that supports and rotates the substrate W. The spin head 340 is disposed within the processing container 320. The spin head 340 supports the substrate W and rotates the substrate W during the process progress. The spin head 340 has a body 342, a support pin 344, a chuck pin 346, and a support shaft 348. The body 342 has a top surface that is substantially circular when viewed from above. The support shaft 348 that is rotatable by a motor 349 is fixedly coupled to the lower surface of the body 342. A plurality of support pins 344 is provided. The support pins 344 are spaced apart at the edge of an upper surface of the body 342 at predetermined intervals and protrude upwardly from the body 342. The support pins 334 are arranged in combination with each other to have an overall annular ring shape. The support pin 344 supports an edge of the rear surface of the substrate W so that the substrate W is spaced apart from the upper surface of the body 342 at a predetermined distance. A plurality of chuck pins 346 is provided. The chuck pin 346 is disposed further from the center of the body 342 than the support pin 344. The chuck pin 346 is provided to protrude upwardly from the body 342. The chuck pin 346 supports a lateral portion of the substrate W such that the substrate W does not move laterally from a regular position when the spin head 340 is rotated. The chuck pin 346 is provided to be linearly movable between a standby position and a support position along a radial direction of the body 342. The standby position is a position further away from the center of the body 342 relative to the support position. When the substrate W is loaded to or unloaded from the spin head 340, the chuck pin 346 is positioned in the standby position, and when the process is performed on the substrate W, the chuck pin 346 is positioned in the support position. In the support position, the chuck pin 346 is in contact with the lateral portion of the substrate W.

The lifting unit 360 adjusts the relative height between the processing container 320 and the spin head 340. The lifting unit 360 linearly moves the processing container 320 in the up and down direction. As the processing container 320 moves in the vertical direction, the relative height of the processing container 320 with respect to the spin head 340 changes. The lifting unit 460 includes a bracket 360, a moving shaft 362, and a driver 364. The bracket 362 is fixedly installed on the outer wall of the processing container 320, and a moving shaft 364, which is moved in the vertical direction by a driver 366, is fixedly coupled to the bracket 364. The processing container 320 is lowered so that the spin head 340 protrudes over the top of the processing container 320 when the substrate W is placed on or lifted from the spin head 340. In addition, when the process is in progress, the height of the processing container 320 is adjusted so that the treatment solution flows into the predetermined recovery container 326 according to the type of the treatment solution that has been supplied to the substrate W.

Unlike the description above, the lifting unit 360 may move the spin head 340 in the vertical direction instead of the processing container 320.

The liquid discharge unit 400 supplies various types of liquids to the substrate W. The liquid discharge unit 400 further includes a plurality of nozzles 410 to 430. Each nozzle is moved to a process position and a standby position by a nozzle position driver 440. A process position is defined herein as a position where the nozzles 410 to 430 are capable of discharging liquid onto the substrate W positioned within the processing container 320, and a standby position is defined as a position where the nozzles 410 to 430 are waiting outside of the process position. According to an example, the process position may be a position at which the nozzles 410 to 430 may supply a liquid to the center of the substrate W. For example, when viewed from above, the nozzles 410 to 430 may be moved linearly or axially to be moved between the process position and the standby position. The treatment solution discharged from the liquid discharge unit 400 onto the substrate W may be a liquefied treatment solution. Additionally, in the standby position, a recovery pipe 450 may be disposed below the third nozzle 430. The recovery pipe 450 recovers the chemical liquid when the third nozzle 430 discharges the chemical liquid for cleaning.

The plurality of nozzles 410 to 430 discharges different types of liquid. The treatment solution discharged from the nozzles 410 to 430 may include at least one of a chemical, a rinse solution, a cleaning solution, and a drying fluid. Referring to the exemplary embodiment of FIG. 2, a first nozzle 410 may be a nozzle for discharging chemicals. For example, the chemical may be a liquid capable of etching a film formed on the substrate W or removing particles remaining on the substrate W. The chemical may be a liquid having a property of strong acid or strong base. The chemical may include sulfuric acid, hydrofluoric acid, or ammonia. Further, the second nozzle 420 may be a nozzle for discharging a rinse solution. The rinse solution may be a solution capable of rinsing the chemicals remaining on the substrate W. For example, the rinse solution may be pure water. Further, the second nozzle 420 may be a nozzle that discharges a cleaning solution. The cleaning solution may be a solution that treats the support unit 340, the processing container 320, and the recovery pipe 450 after processing the substrate W. Further, the third nozzle 430 may be a nozzle for discharging a drying fluid. The drying fluid may be provided as a solution capable of substituting the residual rinse solution on the substrate W. The drying fluid may be a solution having lower surface tension than the rinse solution. The drying fluid may be an organic solvent. For example, the drying fluid may be isopropyl alcohol (IPA). The third nozzle 430 may be connected to the liquid supply unit 600 to receive the drying fluid.

The airflow formation unit 500 forms a downward airflow in the processing space 312. The airflow formation unit 500 supplies airflow from a top portion of the chamber 310 and exhausts airflow from a lower portion of the chamber 310. The airflow formation unit 500 further includes an airflow supply unit 520 and an exhaust unit 540. The airflow supply unit 520 and the exhaust unit 540 are positioned facing each other in the vertical direction.

The airflow supply unit 520 supplies gas in the downward direction. The gas supplied from the airflow supply unit 520 may be air from which impurities are removed. The airflow supply unit 520 further includes a fan 522, an airflow supply line 524, a supply valve 528, and an airflow filter 526. The fan 522 is installed on the ceiling surface of the chamber 310. When viewed from above, the fan 522 is positioned to face the processing container. The fan 522 may be positioned to provide air toward the substrate W positioned within the processing container. The airflow supply line 524 is connected to the fan 522 to supply air to the fan 522. A supply valve 528 is installed in the airflow supply line 524 to regulate the amount of airflow supplied. The airflow filter 526 is installed in the airflow supply line 524 to filter the air. For example, the airflow filter 526 may remove particles and moisture contained in the air.

The exhaust unit 540 exhausts the processing space 312. The exhaust unit 540 further includes an exhaust pipe 542, a pressure reducing member 546, and an exhaust valve 548. The exhaust pipe 542 is installed on the bottom surface of the chamber 310 and is provided as a pipe to exhaust the processing space 312. The exhaust pipe 542 is positioned such that an exhaust port faces upwardly. The exhaust pipe 542 is positioned such that the exhaust port is in communication with the interior of the processing container. That is, the top of the exhaust pipe 542 is located within the processing container. Accordingly, the downward airflow formed within the processing container is exhausted through the exhaust pipe 542.

The pressure reducing member 546 reduces pressure of the exhaust pipe 542. A negative pressure is formed in the exhaust pipe 542 by the pressure reducing member 546, which exhausts the processing container. The exhaust valve 548 is installed in the exhaust pipe 542 and opens and closes the exhaust port of the exhaust pipe 542. The exhaust valve 548 regulates the exhaust volume.

FIG. 3 is a view schematically illustrating the liquid supply unit 600 of FIG. 2.

The liquid supply unit 600 includes a common line part 700 and an individual line part 800. Here, the common line part 700 of the liquid supply unit 600 corresponds to a line that the plurality of substrate processing apparatuses 300 uses in common when processing the substrate W, and the individual line part 800 correspond to a plurality of lines connecting the common line part 700 and each of the plurality of substrate processing apparatuses 300.

First, describing the common line part 700 of the liquid supply unit 600 with further reference to FIG. 3, the common line part 700 of the liquid supply unit 600 further includes a first tank unit 610, a second tank unit 620, a first heating unit 640, and a second heating unit 660. The liquid supply unit 600 is connected to the liquid discharge unit 400. More specifically, the liquid supply unit 600 is connected to individual line part 800 to supply a drying fluid to the third nozzle 430 formed in each liquid discharge unit 400.

The first tank unit 610 further includes a first tank 612. The first tank 612 is formed in the shape of a barrel with a receiving space 612a formed inside. The interior of the first tank 612 receives a drying fluid. The receiving space 612a of the first tank 612 receives isopropyl alcohol. The first tank 612 is connected to the circulation line 641 described later. The first tank 612 may be connected to a supply line 661 described later.

The first tank unit 610 further includes a heater 614. The heater 614 is installed in the receiving space 612a of the first tank 612. The heater 614 may be installed to be immersed in the organic solvent received in the first tank 612. The third heater 614 may regulate a temperature of the organic solvent received in the first tank 612. In one example, the heater 614 may heat the organic solvent received in the first tank 612 to a temperature equal to or higher than the boiling point of the organic solvent, or may heat the organic solvent received in the first tank 612 at a temperature lower than the boiling point. The heater 614 may be set to have the same temperature as a first heater 642 or a second heater 662 described later.

The first tank unit 610 further includes a vacuum pump 616. The vacuum pump 616 is installed in the first tank 612. The vacuum pump 616 may be installed on a vacuum line 615 that is connected to the first tank 612. In one example, the vacuum line 615 may be connected to an upper wall of the first tank 612. The vacuum pump 616 provides vacuum pressure to the receiving space 612a via the vacuum line 615 that is connected to the first tank 612. The vacuum pump 616 provides negative pressure to the receiving space 612a via the vacuum line 615 that is connected to the first tank 612. The vacuum pump 616 may maintain the receiving space 612a of the first tank 612 in a negative pressure atmosphere. This may prevent dissolved gas remaining in the receiving space 612a from infiltrating the degassed organic solvent through the first heating unit 640.

The first tank unit 610 further includes a discharge unit 617. The discharge unit 617 discharges the drying fluid received in the first tank 612 to the outside. In one example, the discharge unit 617 may discharge the drying fluid to the outside when the drying fluid received in the first tank 612 is contaminated or when the drying fluid is due for replacement. The discharge unit 617 further includes a discharge line 617a, and an open/close valve 617b installed on the discharge line 617a. The discharge line 617a may be connected to a lower wall of the first tank 612. The discharge line 617a is a movement path for the treatment solution to be discharged to the outside. The open/close valve 617b may be installed on the discharge line 617a to regulate the discharge amount of drying fluid received in the first tank 612. In one example, the open/close valve 617b may be kept closed when discharge of the drying fluid received in the first tank 612 is not required, and the open/close valve 617b may be kept open when the drying fluid received in the first tank 612 is discharged.

The second tank unit 620 may have the same structure as the first tank unit 610. The second tank unit 620 and the first tank unit 610 may receive the same treatment solution. Specifically, the second tank unit 620 further includes a second tank 622 having a receiving space 622a, a heater 624 installed in the receiving space 622a, a vacuum pump 626 installed on a vacuum line 625, and a discharge unit 627 including a discharge line 627a and an open/close valve 627b. Since the second tank unit 620 has the same structure and function as the first tank unit 610, a detailed description of each configuration of the second tank unit 620 is omitted herein, and reference may be made to the description of the first tank unit 610 as necessary.

The first heating unit 640 further includes a circulation line 641. The circulation line 641 is connected to the first tank 612 to circulate the drying fluid received in the first tank 612. The circulation line 641 is connected to the second tank 622 to circulate the drying fluid received in the second tank 622. The circulation line 641 further includes a first circulation line 641a connected to an upper wall of the first tank 612, a second circulation line 641b connected to a lower wall of the first tank 612, and a third circulation line 641c connecting the first circulation line 641a and the second circulation line 641b. Further, the circulation line 641 further includes a fourth circulation line 641d connected to an upper wall of the second tank 622, and a fifth circulation line 641e connected to a lower wall of the second tank 622. In this case, the third circulation line 641c connects the fourth circulation line 641d and the fifth circulation line 641e. The first circulation line 641a, the third circulation line 641c, and the fourth circulation line 641d join at a first point P1, and the second circulation line 641b, the third circulation line 641c, and the fifth circulation line 641e join at a second point P2. In other words, the third circulation line 641c may be a line connecting between the first point P1 and the second point P2.

Each of the first circulation line 641a, the second circulation line 641b, the fourth circulation line 641d, and the fifth circulation line 641e is equipped with an open/close valve 644. Each of the open/close valves 644 may be selectively turned on or off to form a circulation path for the drying fluid described herein. The first circulation line 641a, the second circulation line 641b, and the third circulation line 641c form a first circulation path in which the drying fluid received in the receiving space 621a of the first tank 621 is circulated. The third circulation line 641c, the fourth circulation line 641d, and the fifth circulation line 641e form a second circulation path in which the drying fluid received in the receiving space 621a of the second tank 622 is circulated. When the drying fluid received in the first tank 621 is circulated through the first circulation path, the drying fluid received in the second tank 622 is not circulated through the second circulation path. In this case, the open/close valves 644 installed on the first and second circulation lines 641a and 641b may be controlled to open, and the open/close valves 644 installed on the fourth and fifth circulation lines 641d and 641e may be controlled to close. Conversely, when the drying fluid received in the first tank 612 is not circulated through the first circulation path and the drying fluid received in the second tank 622 is circulated through the second circulation path, the open/close valves 644 installed on the fourth and fifth circulation lines 641d and 641e may be controlled to open and the open/close valves 644 installed on the first and second circulation lines 641a and 641b may be controlled to close.

The first heating unit 640 further includes a first heater 642. The first heater 642 is installed in the third circulation line 641c. The first heater 642 heats the drying fluid flowing inside the circulation line 641. The first heater 642 may heat the drying fluid flowing inside the circulation line 641 to a temperature equal to or higher than the boiling point of the drying fluid. For example, when the drying fluid is isopropyl alcohol (IPA), the first heater 642 may heat the isopropyl alcohol (IPA) to a temperature equal to or higher than the boiling point of the isopropyl alcohol (IPA), which is 83° C. As the isopropyl alcohol (IPA) is heated to the boiling point or higher and thus boils, and during this process, dissolved gas dissolved in the isopropyl alcohol (IPA) may be degassed as bubbles and discharged. In this case, the amount of dissolved gas in the isopropyl alcohol (IPA) heated to the boiling point or higher through circulation through the circulation line 641 remains very low, and then, in the supply process through the supply line 661, it is possible to minimize bubbles generated from local pressure changes due to changes in pipe diameter, head difference, passage through resistors, or pipe inner surface roughness. This may significantly reduce the possibility that bubbles will fall onto the substrate W together with the IPA when the IPA is discharged onto the substrate W, which may achieve the effect of reducing particles on the substrate W.

Meanwhile, the first heater 642 may heat the drying fluid flowing through the interior of the circulation line 641 to a temperature equal to or higher than the boiling point for a predetermined time. In this case, the predetermined time may be such that the amount of solution is not significantly reduced due to artificial boiling through boiling point heating. Further, the predetermined time may vary depending on the type of solution flowing through the interior of the circulation line 641.

The first heating unit 640 further includes a pump 643. The pump 643 provides power to allow the drying fluid contained in the first tank 612 or the second tank 622 to move within the circulation line 641. In one example, the pump 643 may be a pressure reducing pump. The pump 643 may be provided on the third circulation line 641c. In this case, when the drying fluid contained within the first tank 612 is circulated along the first circulation path or the drying fluid contained within the second tank 622 is circulated along the second circulation path, both circulations may be performed through a single pump 643, which has the effect of simplifying the structure.

The second heating unit 660 further includes the supply line 661. The supply line 661 is connected to the first tank 612 to supply the drying fluid received in the first tank 612 to the substrate W. The supply line 661 is connected to the second tank 622 to supply the drying fluid received in the second tank 622 to the substrate W. The supply line 661 further includes a first supply line 661a connected to the upper wall of the first tank 612, a second supply line 661b connected to the lower wall of the first tank 612, a third supply line 661c connected to the upper wall of the second tank 622, and a fourth supply line 661d connected to the lower wall of the second tank 662. Here, the first supply line 661a and the third supply line 661c join at a third point P3, and the second supply line 661b and the fourth supply line 661d join at a fourth point P4. The supply line 661 further includes a fifth supply line 661e connected to the first and third supply lines 661a and 661c at the point P3, and a sixth supply line 661f connected to the second and fourth supply lines 661b and 661d at the point P4. The fifth supply line 661e and the sixth supply line 661f join at one point and are connected with the nozzle 430.

Each of the first supply line 661a, the second supply line 661b, the third supply line 661c, and the fourth supply line 661d is equipped with an open/close valve 669. Each of the open/close valves 669 may be selectively turned on or off to form a supply path for the drying fluid described later. The first supply line 661a, the second supply line 661b, the fifth supply line 661e, and the sixth supply line 661f form a first supply path through which the drying fluid received in the first tank 612 is supplied to the substrate W via the nozzle 430. The third supply line 661c, the fourth supply line 661d, the fifth supply line 661e, and the sixth supply line 661f form a second supply path through which the drying fluid contained in the second tank 622 is supplied to the substrate W via the nozzle 430. When the drying fluid received in the first tank 621 is supplied through the first supply path, the drying fluid received in the second tank 622 is not supplied through the second supply path. In this case, the open/close valves 669 installed on the first and second supply lines 661a and 661b may be controlled to open, and the open/close valves 669 installed on the third and fourth supply lines 661d and 662e may be controlled to close. Conversely, when the drying fluid received in the first tank 612 is not supplied via the first supply path and the drying fluid received in the second tank 622 is supplied via the second supply path, the open/close valves 649 installed on the third and fourth supply lines 661c and 661d may be controlled to open and the open/close valves 669 installed on the first and second supply lines 661a and 661b may be controlled to close.

Furthermore, when the drying fluid received in the first tank 612 is circulated through the first circulation path, the open/close valve 669 installed on the first supply path is controlled to close and the open/close valve 669 installed on the second supply path is controlled to open. Conversely, when the drying fluid contained in the second tank 622 is circulated through the second circulation path, the open/close valve 669 installed on the first supply path is controlled to open and the open/close valve 669 installed on the second supply path is controlled to close. That is, the first circulation path and the second supply path are operated together and the second circulation path and the first supply path are operated together. In this way, the drying fluid in the second tank 622 is supplied to the substrate W while the drying fluid in the first tank 612 circulates in the first circulation path and degasses the dissolved gas into bubbles. In this case, the drying fluid in the second tank 622 may already be heated to the boiling point or higher by circulation and the bubbles may have been degassed. When the drying fluid in the second tank 622 is all exhausted, the bubble-degassed drying fluid received in the first tank 612 is supplied to the substrate W, and the second tank 622 may be filled with drying fluid and perform the process of degassing dissolved gases into bubbles while the drying fluid is circulated along the second flow path.

The second heating unit 660 further includes the second heater 662. The second heater 662 heats the drying fluid flowing inside the supply line 661. The second heater 662 heats the drying fluid flowing inside the supply line 661 to a temperature that is lower than the boiling point of the drying fluid. For example, when the drying fluid is isopropyl alcohol (IPA), the second heater 662 may heat the isopropyl alcohol (IPA) to a temperature lower than the boiling point of isopropyl alcohol (IPA), which is 83° C. Preferably, the second heater 662 may heat isopropyl alcohol (IPA) to a temperature between 65° C. and 75° C. and supply heated isopropyl alcohol (IPA) onto the substrate W. In this case, the drying fluid, which has been heated to the boiling point or higher by the first heating unit 640 and degassed of dissolved gas into bubbles may be supplied onto the substrate through the nozzle 430 along the supply line 661 while maintaining a temperature below the boiling point by the second heating unit 660. In this way, the drying fluid that has been already degassed of dissolved gas is suppressed from generation of bubbles even in local pressure changes due to changes in pipe diameter, head difference, passage through resistors, or pipe inner surface roughness as it flows through the supply line 661, and the reduction of particles on the substrate W is achieved.

The second heater 662 is installed on the sixth supply line 661f. Referring to FIG. 3, the second heater 662 may be installed upstream of the junction of the fifth supply line 661e and the sixth supply line 661f. In this case, upstream refers to a location adjacent to the outlet from which the treatment solution supply from the first tank 612 or the second tank 622 begins, and downstream refers to the opposite location. The direction from upstream to downstream means the direction in which the treatment solution is discharged from the tanks 612 and 622 and is supplied to the nozzle 430, and means the direction away from the outlets of the tanks 612 and 622. The outlet of the first tank 612 is formed on the lower wall of the first tank 612 connected with the second supply line 661b, and the outlet of the second tank 622 is formed on the lower wall of the second tank 622 connected with the fourth supply line 661d. Further, upstream may mean a location adjacent to the fourth point P4, which is the junction of the second supply line 661b and the fourth supply line 661d.

The second heating unit 660 further includes a pump 663. The pump 663 provides power to allow the drying fluid received in the first tank 612 or the second tank 622 to move within the supply line 661. In one example, the pump 663 may be a pressure reducing pump. The pump 663 may be installed on the sixth supply line 661f. In this case, when the drying fluid received within the first tank 612 is supplied along the first supply path or when the drying fluid received within the second tank 622 is circulated along the second supply path, both circulations may be performed through a single pump 663, which has the effect of simplifying the structure.

The second heating unit 660 further includes a first pressure sensor 664. The first pressure sensor 664 is provided on the sixth supply line 661f. The first pressure sensor 664 is installed upstream of the junction of the fifth supply line 661e and the sixth supply line 661f. The first pressure sensor 664 may sense the flow pressure of the drying fluid before the drying fluid is supplied to the nozzle 430. The first pressure sensor 664 may detect changes in the flow rate of the drying fluid passing through the interior of the sixth supply line 661f. Alternatively, the first pressure sensor 664 may detect a change in pressure of the drying fluid flowing through the sixth supply line 661f.

The second heating unit 660 further includes a filter 665. The filter 665 is provided on the sixth supply line 661f. The filter 665 is installed upstream of the junction of the fifth supply line 661e and the sixth supply line 661f. The filter 665 filters out any residual contaminants, particles, etc. that remain in the drying fluid before the drying fluid is supplied to the nozzle 430.

The second heating unit 660 further includes a flow meter 666. The flow meter 666 is provided on the sixth supply line 661f. The flow meter 666 is installed upstream of the junction of the fifth supply line 661e and the sixth supply line 661f. The flow meter 666 measures the flow rate of the drying fluid flowing through the supply lines 661. In one example, the flow meter 666 may measure the flow rate by measuring a change in unit area or a change in mass per hour of the drying fluid flowing through the sixth supply line 661f. However, without limitation, various methods may be employed to measure a flow rate of the drying fluid flowing through the supply line 661.

The pump 663, the second heater 662, the first pressure sensor 664, the filter 665, and the flow meter 666 installed on the sixth supply line 661f described above may be installed in sequence from upstream to downstream. However, the present invention is not limited thereto, and some of these configurations may be omitted. In addition, a bubble cutter (not illustrated) may be further installed between the filter 665 and the flow meter 666 to remove any residual bubbles in the fluid.

The second heating unit 660 further includes a second pressure sensor 667. The second pressure sensor 667 is installed on the fifth supply line 661e. The second pressure sensor 667 is installed downstream of the junction of the fifth and sixth supply lines 661e and 661f. The second pressure sensor 667 measures the pressure of the drying fluid that is left after being supplied to the nozzle 430 along the sixth supply line 661f flows through the interior of the fifth supply line 661e.

The second heating unit 660 further includes a static pressure regulator 668. The static pressure regulator 668 is installed on the fifth supply line 661e. The static pressure regulator 668 is installed downstream of the junction of the fifth and sixth supply lines 661e and 661f. The static pressure regulator 668 is installed downstream of the second pressure sensor 667 on the fifth supply line 661e. The static pressure regulator 668 may be adjusted to maintain a constant pressure within the entire supply line 661 based on the pressure value measured by the second pressure sensor 667 and the pressure value measured by the first pressure sensor 664.

Next, the individual line part 800 of the liquid supply unit 600 will be described, and the liquid supply unit 600 includes a plurality of individual line parts 800, each of which is connected with each of the plurality of substrate processing apparatuses 300. These individual line parts 800 are connected to the plurality of substrate processing apparatuses 300, and each of the substrate processing apparatuses 300 discharges drying fluid under control of the controller 900.

Accordingly, the individual line part 800 of the liquid supply unit 600 includes an individual line 801, an individual line-side flow meter 802, an individual line-side flow regulating valve 803, an individual line-side temperature sensor 804, an individual line-side supply control valve 805, an individual line-side recovery line 806, and an individual line-side recovery valve 807.

The individual line 801 has one end connected to the sixth supply line 661f and the other end connected to the nozzle 430. The individual lines 801 may be provided in plural and are connected to the plurality of substrate processing apparatuses 300, respectively. These individual line 801 forms a path for the drying fluid circulated through the common line part 700 to be discharged to the nozzle 430.

The individual line-side flow meter 802 is installed in the individual line 801. The individual line-side flow meter 802 measures the flow rate of the individual line 801 and provides the operator with information about the flow rate of the drying fluid discharged through the individual line 801.

The individual line-side flow regulating valve 803 is installed on the individual line 801. In this case, the individual line-side flow control valve 803 may be installed between the individual line-side flow meter 802 and the nozzle 430. These individual line-side flow control valve 803 regulates the flow rate discharged to the nozzle 430 according to a regulated value. Thus, the flow rate discharged from each of the substrate processing apparatuses 300 may be regulated by the individual line-side flow regulating valve 803 installed in each of the substrate processing apparatuses 300. In this case, the substrate processing apparatus 300 may adjust the amount of drying fluid discharged by adjusting the individual line-side flow regulating valve 803 according to the processing process.

The individual line-side temperature sensor 804 is installed on the individual line 801. The individual line-side temperature sensor 804 may measure the temperature of the drying fluid supplied to each of the substrate processing apparatuses 300 and transmit the measured temperature value to the controller 900. In this case, the controller 900 may receive and monitor the temperature value of the drying fluid from the individual line-side temperature sensor 804, and may generate a warning alarm when the temperature value of the drying fluid supplied through the individual line 801 exceeds a preset value.

The individual line-side supply control valve 805 is installed on the individual line 801. In this case, the individual line-side supply control valve 805 may be installed between the individual line-side flow regulating valve 803 and the nozzle 430. The individual line-side supply control valve 805 may be controlled in an open or closed state by the controller 900. In this case, the individual line-side supply control valve 805 may be controlled by the controller 900 to be opened only while the substrate processing apparatus 300 is processing the substrate W to allow the drying fluid to be supplied to the nozzle 430 and may be closed to prevent the drying fluid from being supplied to the nozzle 430 when the substrate W is not being processed. In this case, the individual line-side supply control valve 805 is formed as a three-way valve, so that when the individual line-side supply control valve 805 is closed to prevent the supply of the drying fluid to the nozzle 430 side, the drying fluid is recovered through the individual line-side recovery line 806.

The individual line-side recovery line 806 connects between the individual line-side supply control valve 805 and the fifth supply line 661e of the common line part 700. The individual line-side recovery line 806 forms a path for the drying fluid to be recovered to the common line part 700 in the event that the individual line-side supply control valve 805 is closed to prevent the drying fluid from being supplied to the nozzle 430 side.

The individual line-side recovery valve 807 is installed in the individual line-side recovery line 806. This individual line-side recovery valve 807 has an open state controlled by the controller 900, and may be switched to a closed state to prevent the drying fluid from being recovered when a situation such as a check of the substrate processing apparatus 300 or a check light of the common line part 700 occurs, when a situation in which the drying fluid is discharged more than a certain number of times occurs, or when an operation to regulate the flow rate of the drying fluid occurs.

Meanwhile, the controller 900 controls each of the plurality of open/close valves 644 provided on the circulation line 641. The controller 900 controls each of the plurality of open/close valves 669 provided on the supply line 661. The controller 900 may control each of the open/close valve 644 provided on the first circulation path, the open/close valve 644 provided on the second circulation path, the open/close valve 669 provided on the first supply path, and the open/close valve 669 provided on the second supply path. The controller 900 may control the simultaneous opening or closing of the open/close valve 664 provided in the first circulation path and the open/close valve 669 provided in the second supply path, and may control the simultaneous opening or closing of the open/close valve 664 provided in the second circulation path and the open/close valve 669 provided in the first supply path. When the controller 900 controls the open/close valves provided on the first circulation path and the second supply path to open, the controller 900 controls the open/close valves provided on the second circulation path and the first supply path to close. Conversely, the controller 900 may control the open/close valves provided on the first circulation path and the second supply path to be closed when the open/close valves provided on the second circulation path and the first supply path are controlled to be open.

Hereinafter, the movement process of the treatment solution in the liquid supply unit 600 will be described in detail with reference to FIGS. 5 and 6.

FIGS. 5 and 6 are diagrams illustrating a movement process of the treatment solution flowing in the liquid supply unit of FIG. 3. In more detail, FIG. 5 is a diagram illustrating the process of the flow of treatment solution in the liquid supply unit 600 through the first circulation path and the second circulation path, and FIG. 6 is a diagram illustrating the process of the flow of treatment solution in the liquid supply unit 600 through the second circulation path and the first circulation path.

Referring to FIGS. 5 and 6, the first circulation line 641a, the second circulation line 641b, and the third circulation line 641c form the first circulation path in which the drying fluid received in the receiving space 621a of the first tank 621 is circulated. The third circulation line 641c, the fourth circulation line 641d, and the fifth circulation line 641e form the second circulation path in which the drying fluid received in the receiving space 621a of the second tank 622 is circulated. Further, the first supply line 661a, the second supply line 661b, the fifth supply line 661e, and the sixth supply line 661f form the first supply path. The third supply line 661c, the fourth supply line 661d, the fifth supply line 661e, and the sixth supply line 661f form the second supply path.

Referring to FIGS. 5 and 6, the drying fluid in the first tank 612 is heated to a temperature equal to or higher than the boiling point while circulating along the first circulation path, during which dissolved gas in the drying fluid is degassed into bubbles and discharged. The bubble degassing process through the first circulation path continues for a period of time, and the degassed drying fluid is received in the first tank 612. In the first tank 612, the vacuum pump 626 creates a vacuum atmosphere in the receiving space 612a to prevent other gas from being re-dissolved in the bubble degassed drying fluid. The drying fluid in the second tank 622 flows to the individual line 801 along the second supply path and is supplied to the substrate W through the nozzle 430 connected to the individual line 801. Here, the individual line-side supply control valve 805 is controlled by the controller 900 to be in an open state so that the drying fluid is discharged to the nozzle 430 side. In this case, the drying fluid received in the second tank 622 may be a drying fluid in the bubble degassed state. The drying fluid in the second tank 622 is supplied to the substrate W while maintaining at a temperature below the boiling point by the second heater 662. Even when the localized pressure changes (e.g., pressure drops) that the drying fluid experiences as it moves along the supply line 661 occur, the drying fluid that has already been degassed of bubbles generates relatively fewer bubbles than the drying fluid that has not. In this case, the amount of bubbles generated is low, which leads to a particle reduction effect on the substrate W, even though the drying fluid is supplied to the substrate W. After all of the drying fluid received in the second tank 622 has been supplied to the substrate W, the drying fluid waiting in the first tank 612 in the bubbles degassed state flows to the individual line 801 along the first supply path and is supplied to the substrate W through the nozzle 430 connected to the individual line 801. Here, the individual line-side supply control valve 805 is controlled by the controller 900 to be in the open state so that the drying fluid is discharged to the nozzle 430 side. The emptied second tank 622 is again supplied with the drying fluid, and the bubble degassing process proceeds through the second circulation path. The bubble degassing process by the second circulation path is the same as the bubble degassing process by the first circulation path. In this case, the controller 900 controls the open/close valve 644 provided in the first circulation path to close, and controls the open/close valve 644 provided in the second circulation path to open. In addition, the controller 900 controls the open/close valve 669 provided on the first supply path to open and controls the open/close valve 669 provided on the second supply path to close. Further, the individual line-side supply control valve 805 is controlled by the controller 900 to be in a closed state to prevent the drying fluid from being discharged to the nozzle 430.

In the following, a substrate processing method according to an exemplary embodiment of the present invention will be described in detail with reference to the drawings.

FIG. 7 is a flowchart illustrating a process of processing a substrate by using the apparatus of FIG. 3.

A substrate processing method according to an exemplary embodiment of the present invention further includes a chemical supply operation S100, a rinse operation S200, a substitution operation S300, and a drying operation S400.

In the chemical supply operation S100, a chemical is discharged onto the substrate W through the first nozzle 410 to remove metal foreign substances, organic material or particles, and the like remaining on the substrate W. For example, the chemical may be a liquid capable of etching a film formed on the substrate W or removing particles remaining on the substrate W. The chemical may be a liquid having a property of strong acid or strong base. The chemical may include sulfuric acid, hydrofluoric acid, or ammonia. The rinse solution may be a solution capable of rinsing the chemicals remaining on the substrate W.

In the rinse operation S200, pure water (DIW) is discharged onto the substrate W through the second nozzle 420 to remove any chemicals remaining on the substrate W.

In the substitution operation S300, a drying fluid is supplied onto the substrate W through the third nozzle 430 to substitute the rinse solution remaining on the substrate W with the drying fluid. The drying fluid may be a liquid having lower surface tension than the rinse solution. For example, the drying fluid may be isopropyl alcohol (IPA).

The substitution operation S300 further comprises a primary heating operation S320 and a secondary heating operation S340.

The primary heating operation S320 heats the drying fluid to a temperature equal to or higher than the boiling point of the drying fluid to degas bubbles from the drying fluid before supplying the drying fluid to the substrate. In this case, heating the drying fluid to the temperature equal to or higher than the boiling point of the drying fluid is performed while circulating the drying fluid through the circulation line 641 connected to the tanks 612 and 622.

The secondary heating operation S340 supplies the substrate with the drying fluid having a temperature below the boiling point after the primary heating operation S320. In this case, the individual line-side supply control valve 805 is controlled by the controller 900 to be in the open state so that the drying fluid is discharged to the nozzle 430 side. In the secondary heating operation S340, after degassing the bubbles from the drying fluid, the drying fluid is secondarily heated while the drying fluid is supplied to the substrate, but the secondary heating heats the drying fluid to a temperature below the boiling point of the drying fluid. The drying fluid may include isopropyl alcohol. In this case, in the primary heating operation S320, the isopropyl alcohol is heated at a temperature equal to or higher than 83° C., which is the boiling point of the isopropyl alcohol, and in the secondary heating operation S340, the isopropyl alcohol is heated at a temperature below the boiling point of the isopropyl alcohol. In this case, preferably, the heating temperature in the secondary heating operation S340 is between 65 and 75° C.

In the drying operation S400, organic solvents on the substrate may be removed by supplying drying gas to the substrate. In this case, in the drying operation S400, the substrate liquid-treated in the cleaning chamber is transferred by the main robot 244 to the drying chamber (not illustrated) to be dried.

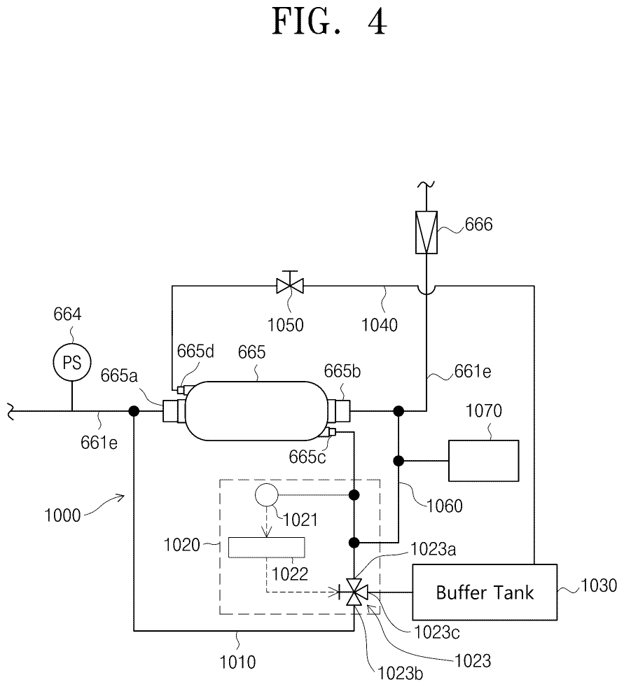

Hereinafter, the circulation unit illustrated in FIG. 4 will be described.

FIG. 4 is a diagram schematically illustrating a circulation unit connected with the filter illustrated in FIG. 3.

As illustrated in FIG. 4, in the substrate processing apparatus according to the exemplary embodiment of the present invention, the liquid supply unit 600 may further include a circulation unit 1000.

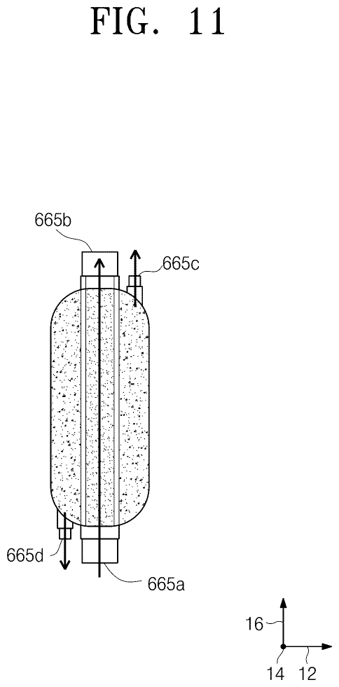

The circulation unit 1000 is connected to a vent port 665c of the filter 665 and circulates the treatment solution discharged from the filter 665 to an inlet port 665a side of the filter 665. Here, as one example of the filter 665, the filter 665 may be configured as a membrane filter. Accordingly, the filter 665 is formed with the inlet port 665a through which the treatment solution flows into and an outlet port 665b through which the filtered treatment solution is discharged, and further includes a vent port 665c for discharging the treatment solution in a full state to remove bubbles in the treatment solution and a drain port 665d for discharging the internal residual treatment solution. In this case, the filter 665 may have the inlet port 665a and the drain port 665d positioned at the bottom, as illustrated in FIG. 11, such that the treatment solution may be discharged in a free-fall manner through the drain port 665d upon discharge. Additionally, the filter 665 may have the outlet port 665b and the vent port 665c positioned at the top so that the filter 665 may discharge the treatment solution through the vent port 665c when the treatment solution is full. As such, the filter 665 may be installed on the fifth supply line 661e to filter the treatment solution flowing on the fifth supply line 661e. Further, the filter 665 may include a plurality of filters, and the plurality of filters 665 may be connected in parallel to each other.

In the meantime, the circulation unit 1000 may further include a circulation line 1010 connecting the vent port 665c of the filter 665 and the inlet port 665a of the filter 665.

Thus, because the treatment solution discharged from the vent port 665c of the filter 665 circulates to the inlet port 665a side of the filter 665, the contaminated treatment solution discharged to the vent port 665c flows into the filter 665 side again, and filtered again. As a result, the contamination source of the treatment solution discharged from the vent port 665c is filtered and does not cause a process defect. Furthermore, since the contaminated treatment solution discharged from the vent port 665c is recirculated to the filter 665 side, the treatment solution discharged from the vent port 665c may be reused to reduce the treatment solution. In this case, one end of the circulation line 1010 may also be connected to the inlet port 665a of the filter 665 via the fifth supply line 661e that is connected to the circulation line 1010.

In addition, the circulation unit 1000 may be installed on the circulation line 1010 to discharge the treatment solution to a buffer tank in the event that bubbles are generated in the treatment solution discharged from the vent port 665c of the filter 665, and to allow the treatment solution to flow in the circulation line 1010 in the event that no bubbles are generated.

As one example of the circulation unit 1000, the circulation unit 1000 may include a bubble detection sensor 1021, a valve controller 1022, and a valve unit 1023.

The bubble detection sensor 1021 is installed in the circulation line. The bubble detection sensor 1021 is installed upstream of the valve unit 1023. The bubble detection sensor 1021 generates a bubble detection signal when an amount of air is detected in the treatment solution flowing in the circulation line.

The valve controller 1022 may be formed of a circuit unit with a control function. The valve controller 1022 interworks with the bubble detection sensor 1021 and the valve unit 1023. When the valve controller 1022 receives a bubble detection signal from the bubble detection sensor 1021, the valve controller 1022 transmits a state transition signal to the valve unit 1023, and the valve unit 1023 receiving the state transition signal switches the state from a first state to a second state. In this case, the valve controller 1022 may switch the state of the valve unit 1023 from the second state to the first state by stopping the output of the state transition signal output to the valve unit 1023 when no bubble detection signal is input for a preset period of time.

Further, the valve controller 1022 may control the valve unit 1023 to cause the treatment solution discharged from the vent port 665c to flow to a drain line 1040 during the initial setup of supplying the treatment solution to the substrate, and then control the valve unit 1023 to cause the treatment solution discharged from the vent port 665c to flow to the line connected to the inlet port 665a. In one example, the setup may be the state where the filter 665 is replaced to a new one, or the state where the filter 665 is emptied of its internal treatment fluid and refilled.

The valve unit 1023 is installed on the circulation line 1010. As such, the valve unit 1023 interworks with the bubble detection sensor 1021. The valve unit 1023 may be formed of a three-way valve including an inlet 1023a, a first outlet 1023b, and a second outlet 1023c. The valve unit 1023 may be formed in the state in which the inlet 1023a and the first outlet 1023b are open and the second outlet 1023c is closed in the first state in which the bubble detection sensor 1021 does not detect a bubble. Thus, when the valve unit 1023 is in the first state, the valve unit 1023 may continuously circulate the treatment solution discharged from the vent port 665c of the filter 665. The valve unit 1023 may be formed in the state in which the inlet 1023a and the second outlet 1023c are open and the first outlet 1023b is closed in the second state in which the bubble detection sensor 1021 detects bubbles. Thus, when the valve unit 1023 is in the second state, the valve unit 1023 may prevent the treatment solution discharged from the vent port 665c of the filter 665 from flowing into the circulation line 1010 and allow the treatment solution to flow toward the buffer tank 1030 to discharge the treatment solution containing bubbles.

The circulation unit 1000 may further include the buffer tank 1030 and the drain line 1040.

The buffer tank 1030 has a receiving space for storing the treatment solution. In this case, the treatment solution stored in the buffer tank 1030 may be drained and disposed when the treatment solution increases above a certain volume. The buffer tank 1030 is connected with the second outlet 1023c of the valve unit 1023. Further, the buffer tank 1030 is connected to the other end of the drain line 1040.

The drain line 1040 has one end connected to the drain port 665d of the filter 665 and the other end connected to the buffer tank 1030. Thus, the filter 665 is able to drain any internal residual treatment fluid to the buffer tank 1030 via the drain line 1040 when draining is required.

As such, the circulation unit 1000 including the drain line 1040 and the buffer tank 1030 ensures that the treatment solution discharged from the drain port 665d of the filter 665 is recovered when the filter 665 is replaced, so that the treatment solution remaining inside the filter 665 is prevented from entering the supply line 661e side when the filter 665 is replaced, thereby preventing a process defect from occurring.

In addition, the circulation unit 1000 may further include a drain valve 1050.

The drain valve 1050 is installed on the drain line 1040. The drain valve 1050 allows the filter 665 to maintain the close state when filter 665 is filtering, thereby preventing the treatment solution from flowing from filter 665 to the buffer tank 1030, and is switched to an open state when filter 665 is replaced, thereby discharging the residual treatment solution inside filter 665 to the buffer tank 1030. Thus, the filter 665 may discharge any internal residual treatment fluid by the drain valve 1050 to the buffer tank 1030 upon replacement.

Further, the circulation unit 1000 may further include a measurement line 1060 and a densitometer 1070.

One end of the measurement line 1060 is connected to the outlet port 665b of the filter 665. Accordingly, the treatment solution discharged from the filter 665 may be supplied to the measurement line 1060. In this case, one end of the measurement line 1060 may be connected to the outlet port 665b of the filter 665 via a fifth supply line 661e that is connected to the measurement line 1060.

The densitometer 1070 is installed on the measurement line 1060. The densitometer 1070 may measure the concentration of the treatment solution discharged from the filter 665 to provide information about the concentration of the treatment solution. Thus, the substrate processing apparatus according to the exemplary embodiment of the present invention may determine whether the concentration of the treatment solution discharged from the filter 665 is a suitable concentration for treatment of the substrate. In this case, the densitometer 1070 measures the treatment solution filtered from the filter 665, so that the concentration of the treatment solution may be measured in a state where the concentration is not altered by contaminants such as particles. Thus, the densitometer 1070 may more accurately measure the concentration of the treatment solution.

Additionally, the other end of the measurement line 1060 may be connected to the circulation line 1010. Thus, the treatment solution flowing in the measurement line 1060 is circulated through the circulation line 1010. Thus, the treatment solution whose concentration is measured by the densitometer 1070 is circulated through the circulation line 1010 after the concentration is measured in the measurement line 1060. Thus, the treatment solution that may be contaminated after the concentration measurement is filtered again by the filter 665, so that the treatment solution that is discarded during the concentration measurement may be recovered and the treatment solution may be reduced.

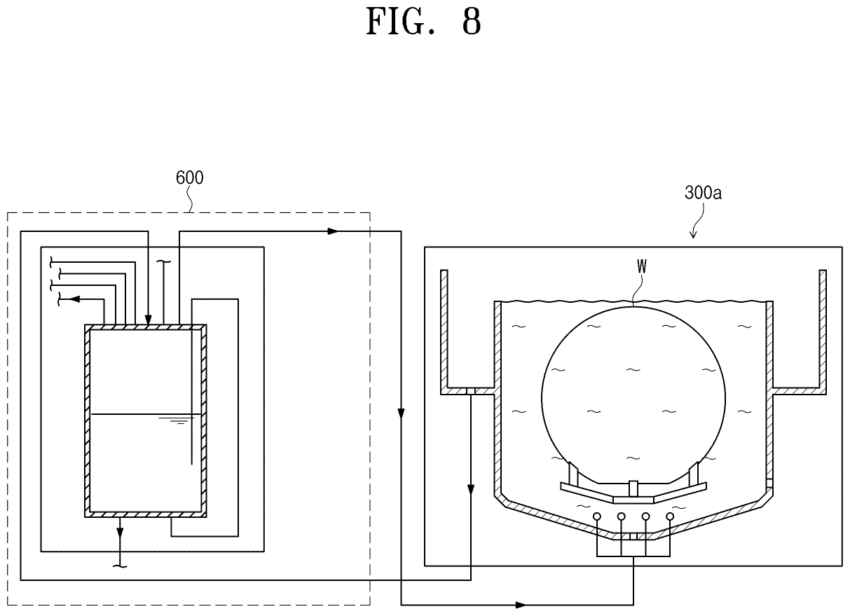

In the example described above, the substrate processing apparatus 300 performing the liquid treatment process was described as a single leaf type for liquid-treating a single sheet of substrate W. However, as illustrated in FIG. 8, the substrate processing apparatus 300a may also be provided in a batch type for liquid-treating a plurality of substrates W simultaneously.

In the following, the movement process of the treatment fluid in the circulation unit will be described.

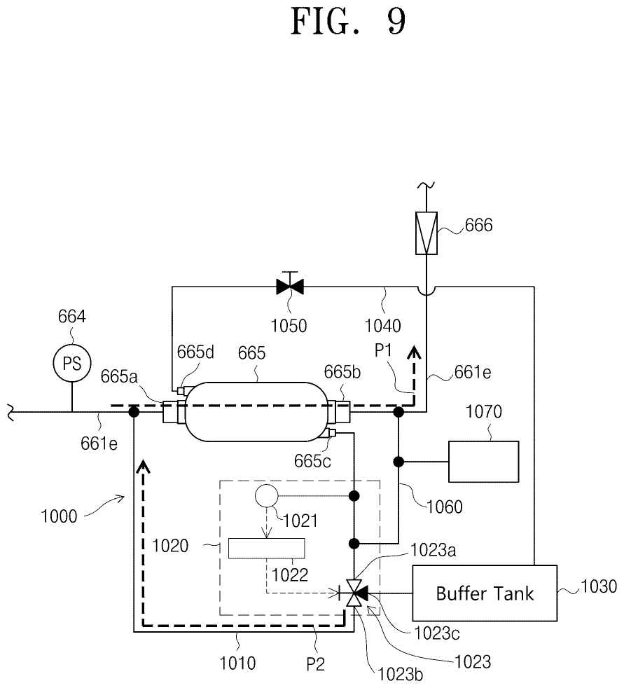

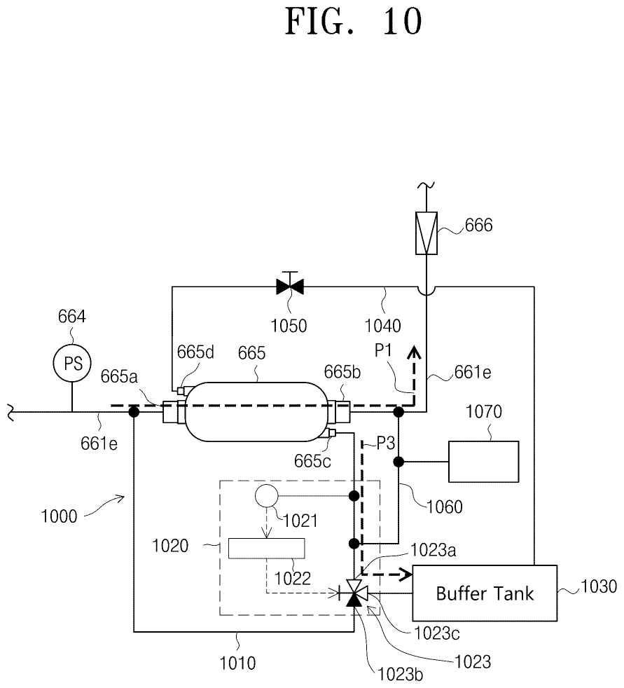

FIG. 9 is a diagram illustrating a path through which the circulation unit illustrated in FIG. 4 filters the treatment solution. FIG. 10 is a diagram illustrating a pathway through which the circulation unit illustrated in FIG. 9 discharges the treatment solution including generated bubbles. FIG. 11 is a diagram illustrating the flow of the discharge of the treatment solution from the filter of FIGS. 9 and 10 with arrows.

As illustrated in FIG. 9, the filter 665 of the circulation unit filters the treatment solution supplied through a supply path P1.

In this case, when the treatment solution is fully filled in the vent port 665c of the filter 665, the treatment solution is circulated along the first path P2 of the circulation line 1010 through the vent port 665c of the filter 665, and the treatment solution flowed into the circulation line 1010 is circulated toward the inlet port 665a of the filter 665 to reuse the treatment solution. In this case, the drain valve 1050 of the drain line 1040 is formed in a closed state so as not to drain the treatment solution.

Meanwhile, when the filter 665 is replaced and the initial setup is performed, residual air remains inside, and the residual air is discharged to the circulation line 1010 through the vent port 665c during the process of the filter 665 being filled with the treatment solution.

In this case, the bubble detection sensor 1021 installed in the circulation line 1010 detects bubbles and generates a bubble detection signal, and transmits the bubble detection signal to the valve controller 1022. The valve controller 1022 that receives the bubble detection signal switches the state of the valve unit 1023 from the first state to the second state.

Then, the valve unit 1023 switches the state to the second state in which the inlet 1023a and the second outlet 1023c are opened and the first outlet 1023b is closed, as illustrated in FIG. 10. Therefore, when the valve unit 1023 is in the second state, the valve unit 1023 prevents the treatment solution discharged from the vent port 665c of the filter 665 from flowing to the first path P2 of the circulation line 1010, and allows the treatment solution to flow toward the buffer tank 1030 along a second path P3. Therefore, the treatment solution containing bubbles do not flow into the process of processing the substrate, and therefore, the treatment solution does not cause process defects due to bubbles.

Meanwhile, the bubble detection sensor 1021 stops generating a bubble detection signal when no bubbles are detected. In this case, the valve controller 1022 switches the valve unit 1023 from the second state to the first state when the bubble detection signal is not input from the bubble detection sensor 1021 for a certain period of time. Then, the treatment solution is circulated along the first path P2 in a state where the discharge of the treatment solution to the buffer tank 1030 is stopped, as illustrated in FIG. 9.

In this way, in the substrate processing apparatus according to the exemplary embodiment of the present invention, the treatment solution discharged from the vent port 665c of the filter 665 is circulated to the inlet port 665a of the filter 665, so that the contaminated treatment solution discharged from the vent port 665c of the filter 665 is filtered again to reduce process defects caused by the treatment solution, and to reduce the treatment solution by reusing the treatment solution. In this case, the treatment solution discharged from the vent port 665c of the filter 665 is discharged to the buffer tank 1030 when the treatment solution contains bubbles, thereby causing no process defects due to bubbles.

As described above, the present invention has been described with reference to the specific matters, such as a specific component, limited exemplary embodiments, and drawings, but these are provided only for helping general understanding of the present invention, and the present invention is not limited to the aforementioned exemplary embodiments, and those skilled in the art will appreciate that various changes and modifications are possible from the description.

Therefore, the spirit of the present invention should not be limited to the described exemplary embodiments, and it will be the that not only the claims to be described later, but also all modifications equivalent to the claims belong to the scope of the present invention.

1. An apparatus for processing a substrate, the apparatus comprising:
a chamber having a processing space;
a support unit for supporting a substrate in the processing space;
a liquid discharge unit for discharging a treatment solution in a liquid form onto the substrate supported on the support unit; and
a liquid supply unit including a tank storing the treatment solution, a supply line connecting the tank and the liquid discharge unit, and a filter installed between the tank and the supply line,
wherein the filter includes:
an inlet port through which the treatment solution flows into the filter from the tank;
an outlet port through which the treatment solution flows out from the filter to the liquid discharge unit; and
a vent port for discharging a liquid containing bubbles to the outside of the filter, and
the liquid supply unit further includes a circulation line which is connected to the vent port of the filter and circulates the treatment solution discharged from the vent port of the filter to a line connected to the inlet port of the filter.

2. The apparatus of claim 1, wherein the liquid supply unit includes:
a drain line branched from the circulation line and draining the treatment solution discharged from the vent port; and
a valve unit for controlling a flow path of the treatment solution so that the treatment solution discharged from the vent port selectively flows to the drain line or the line connected to the inlet port.

3. The apparatus of claim 2, wherein the liquid supply unit further includes a valve controller that controls the valve unit, and
the valve controller controls the valve unit so that the treatment solution discharged from the vent port flows to the line connected to the inlet port when the substrate is processed.

4. The apparatus of claim 2, wherein the liquid supply unit further includes a valve controller that controls the valve unit, and
the valve controller controls the valve unit so that the treatment solution discharged from the vent port flows to the drain line during an initial setup of the filter.

5. The apparatus of claim 4, wherein the initial setup includes replacement of the filter.

6. The apparatus of claim 2, wherein the liquid supply unit further includes:
a bubble detection sensor for detecting bubbles in the circulation line; and
a valve controller for controlling the valve unit, and
the valve controller causes the treatment solution discharged from the vent port to flow to the drain line when the bubbles detected by the bubble detection sensor are equal to or greater than a set amount.

7. The apparatus of claim 6, wherein the valve controller controls the valve unit so that the treatment solution discharged from the vent port flows to the line connected to the inlet port when the bubbles detected by the bubble detection sensor are less than the set amount.

8. The apparatus of claim 2, wherein the liquid supply unit further includes a valve controller that controls the valve unit, and
the valve controller controls the valve unit so that the treatment solution discharged from the vent port flows to the drain line during an initial setup for supplying the treatment solution to the substrate, and then so that the treatment solution discharged from the vent port flows to the line connected to the inlet port.

9. The apparatus of claim 2, wherein the valve unit is a three-way valve installed at a point where the circulation line and the drain line are connected.

10. The apparatus of claim 6, wherein the bubble detection sensor is disposed between the vent port and the three-way valve.

11. The apparatus of claim 1, wherein the liquid supply unit further includes:
a measurement line having one end connected to the outlet port of the filter; and
a densitometer installed on the measurement line, and
the measurement line has the other end connected to the circulation line.

12. The apparatus of claim 1, wherein the filter is a membrane filter.

13. The apparatus of claim 1, wherein the filter further includes a drain port for discharging the internal residual treatment solution therefrom; and
the liquid supply unit further includes a drain valve installed in the drain line and opening and closing a passage of the drain line, and
the drain port is located at a bottom end of the filter, and when the drain valve is open, the treatment solution is drained by falling, and
the vent port is located at a top end of the filter, and when the treatment solution is fully filled in the filter, the treatment solution is discharged upward.

14.-19. (canceled)

20. An apparatus for processing a substrate, the apparatus comprising:
a chamber having a processing space;
a support unit for supporting a substrate in the processing space;
a liquid discharge unit for discharging a treatment solution in a liquid form onto a substrate supported on the support unit; and
a liquid supply unit including a tank storing the treatment solution, a supply line connecting the tank and the liquid discharge unit, and a filter installed between the tank and the supply line,
wherein the filter includes:
an inlet port through which the treatment solution flows into the filter from the tank;
an outlet port through which the treatment solution flows out from the filter to the liquid discharge unit; and
a vent port for discharging a liquid containing bubbles to the outside of the filter, and the liquid supply unit further includes:
a circulation line which is connected to the vent port of the filter and circulates the treatment solution discharged from the vent port of the filter to a line connected to the inlet port of the filter;
a drain line branched from the circulation line and draining the treatment solution discharged from the vent port;
a measurement line having one end connected to the outlet port of the filter and the other end connected to the circulation line;
a densitometer installed on the measurement line;
a valve unit for controlling a flow path of the treatment solution so that the treatment solution discharged from the vent port selectively flows to the drain line or the line connected to the inlet port;
a bubble detection sensor for detecting bubbles in the circulation line; and
a valve controller for controlling the valve unit, and
the valve controller controls the valve unit to cause the treatment solution discharged from the vent port to flow to the drain line when the bubbles detected by the bubble detection sensor are equal to or greater than a set amount, and to cause the treatment solution discharged from the vent port to flow to the line connected to the inlet port when the bubbles detected by the bubble detection sensor are less than the set amount, and
the valve controller controls the valve unit so that the treatment solution discharged from the vent port flows to the drain line at a beginning at which the treatment solution is supplied to the substrate, and thereafter, the treatment solution discharged from the vent port flows to the line connected to the inlet port.
